(19) United States
(12) Patent Application Publication
(10) Pub. No.: US 2026/0045466 A1
(43) Pub. Date: Feb. 12, 2026

(54) CONTROL OF RF POWER DELIVERY IN A DISTRIBUTED RF SYSTEM

(71) Applicant: Applied Materials, Inc., Santa Clara, CA (US)

(72) Inventors: DAVID COUMOU, Webster, NY (US); JACOB HARRELL, Fairport, NY (US); DENNIS BROWN, Pittsford, NY (US); NATHAN RANSOM, Rochester, NY (US); JAMES MCCUSKER, Santa Clara, CA (US)

(21) Appl. No.: 18/796,165

(22) Filed: Aug. 6, 2024

(51) Int. Cl. H01J 37/32

(52) U.S. Cl. CPC H01J 37/3299; H01J 37/32183; H01J 37/32899

(57) ABSTRACT

Embodiments described herein relate to an apparatus that includes an RF power supply and an RF power splitter. In an embodiment, the RF power splitter includes a plurality of outputs, and a plurality of RF impedance matches are electrically coupled to different ones of the plurality of outputs of the RF power splitter. In an embodiment, a plurality of RF sensors are configured to measure a voltage and/or a current along a plurality of transmission lines that couple each of the plurality of outputs of the RF power splitter to a different one of the plurality of RF impedance matches. In an embodiment, the apparatus further includes a controller communicatively coupled to the plurality of RF sensors and the plurality of RF impedance matches. The controller is configured to balance power that passes through the plurality of RF impedance matches with a detuning operation.

### BACKGROUND

### 1) Field

Embodiments of the present disclosure pertain to the field of distributed radio frequency (RF) power delivery systems with improved RF power delivery control.

### 2) Description of Related Art

In semiconductor processing facilities (which are sometimes referred to as fabs), plasma chambers are used to process wafers or other substrates. For example, plasma chambers may be used to deposit layers on a wafer, etch layers on a wafer, treat surfaces on the wafer, and/or the like. In some fabs, a plurality of plasma chambers may receive power from a single power source. For example, in the case of a radio frequency (RF) plasma system, a single RF power source may generate power that is distributed to a plurality of plasma chambers. An RF splitter may receive the output from the RF power source and split the incoming RF power into a plurality of outputs. In order to provide uniform processing outcomes in each of the plurality of chambers, the RF power is ideally split evenly between the plurality of outputs by the RF splitter.

However, there are many different variables that can result in uneven power distribution from the single RF power source to the plurality of plasma chambers. For example, different wear on the each of the chambers, differences along each RF power branch, etc. may result in non-uniform power delivery. In some cases, non-uniform power delivery may result in excess reflected power that is propagated back to the RF power source. The reflected power may damage and/or otherwise negatively impact the RF power source.

### SUMMARY

Embodiments described herein relate to an apparatus that includes a radio frequency (RF) power supply, and an RF power splitter electrically coupled to the RF power supply. In an embodiment, the RF power splitter includes a plurality of outputs. In an embodiment, a plurality of RF impedance matches, are electrically coupled to a different one of the plurality of outputs of the RF power splitter. In an embodiment, a plurality of RF sensors are configured to measure a voltage and/or a current along a different one of a plurality of transmission lines that couple each of the plurality of outputs of the RF power splitter to a different one of the plurality of RF impedance matches. In an embodiment, the apparatus further includes a controller communicatively coupled to the plurality of RF sensors and the plurality of RF impedance matches, and the controller is configured to balance power that passes through the plurality of RF impedance matches with a detuning operation.

Embodiments described herein relate to a method that includes detecting an amount of reflected power along a plurality of branches in a multi-branch RF power delivery system that includes a radio frequency (RF) power source, a power splitter coupled to the RF power source, and a plurality of impedance matches that are coupled to a different output of the power splitter. In an embodiment, the reflected power is detected between the plurality of impedance matches and the power splitter. In an embodiment, the method further includes changing a reflection coefficient for one or more of the plurality of impedance matches by altering one or more variable capacitors of the one or more of the plurality of impedance matches, where a sum of the plurality of reflection coefficients are minimized to reduce an amount of reflected power passed from the power splitter to the RF power source.

Embodiments described herein relate to a method that includes tuning a plurality of impedance matches in a radio frequency (RF) power distribution network, and determining if a load power setpoint is greater than a control threshold for each of the plurality of impedance matches. In an embodiment, the method further includes generating antipolar vectors for reflection coefficients for a first subset of the plurality of impedance matches where the load power setpoint is greater than the control threshold. In an embodiment, the first subset includes an even number of impedance matches.

### BRIEF DESCRIPTION OF THE DRAWINGS

FIG. 1A is a schematic illustration of a processing tool with an RF power delivery system with a single RF power source with an output that is distributed to a plurality of plasma chambers, in accordance with an embodiment.

FIG. 1B is a schematic illustration of a processing tool with an RF power delivery system with a single RF power source with an output that is distributed to a plurality of plasma chambers with an RF sensor along each branch between an RF splitter an each plasma chamber, in accordance with an embodiment.

FIG. 2A is a graph of a 3D power ratio at an input to a splitter with an even number of impedance matches that are detuned, in accordance with an embodiment.

FIGS. 2B-2E are graphs of the power dissipation at different splitter resistors for different branches of the RF power delivery system, in accordance with an embodiment.

FIG. 3A is a graph of a 3D power ratio at an input to a splitter with an odd number of impedance matches that are detuned, in accordance with an embodiment.

FIGS. 3B-3E are graphs of the power dissipation at different splitter resistors for different branches of the RF power delivery system, in accordance with an embodiment.

FIG. 4 is a graph of u vector element positions in a complex plane used for optimizing power balancing, in accordance with an embodiment.

FIG. 5 is a transmission line model with an RF sensor, in accordance with an embodiment.

FIG. 6 is a process flow diagram describing a process for power delivery control in a distributed RF system, in accordance with an embodiment.

FIG. 7 is a process flow diagram of a process for reducing reflected power to an RF power source in a distributed RF system, in accordance with an embodiment.

FIG. 8 illustrates a block diagram of an exemplary computer system of a processing tool, in accordance with an embodiment of the present disclosure.

### DETAILED DESCRIPTION

Distributed radio frequency (RF) power deliver systems with improved RF power delivery control are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modem, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

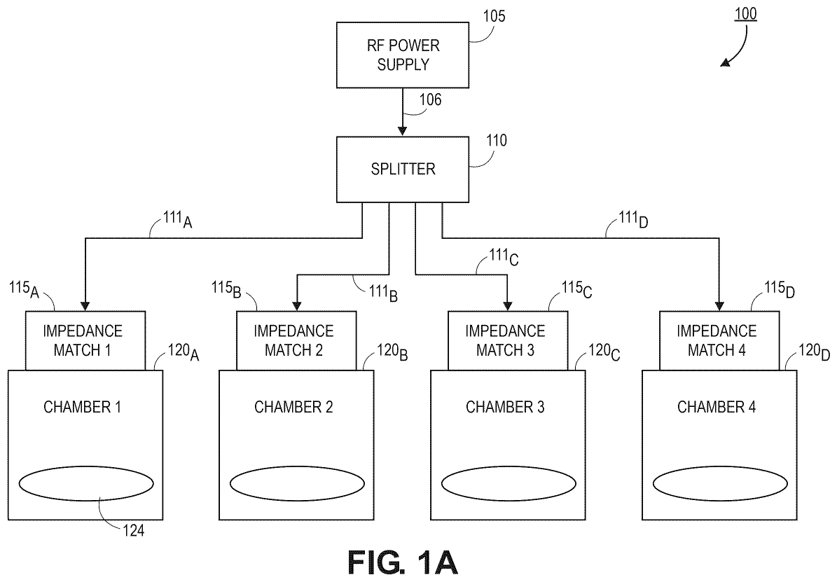

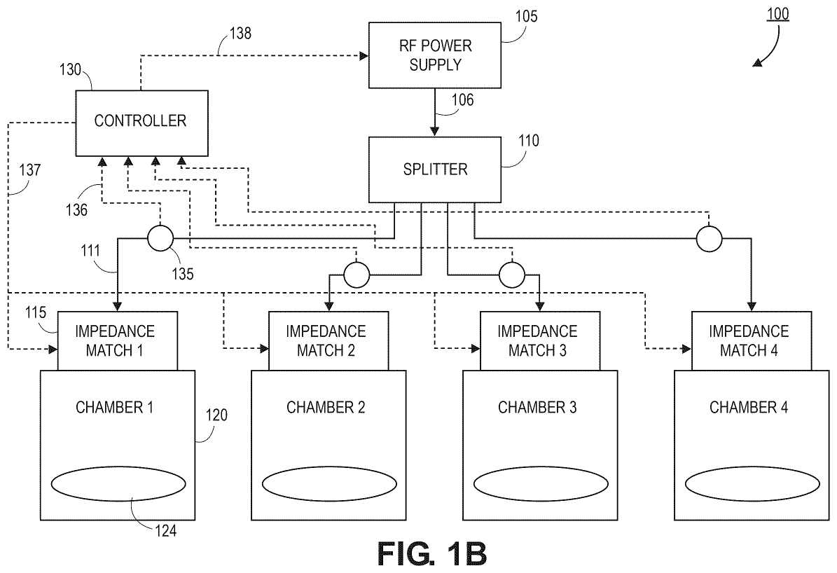

As noted above, distributed radio frequency (RF) power delivery systems rely on precise control of the power delivery along each branch in order to deliver uniform RF power to each of the plasma chambers while minimizing any reflected power that can damage or negatively impact the RF power source. An example of a distributed RF power delivery system 100 is shown in FIG. 1A. As shown, a single RF power supply 105 may be used to supply RF power to a plurality of plasma chambers 120. For example, a set of four plasma chambers 120_{A}-120_{D} is shown in FIG. 1A. In an embodiment, a wafer 124 (or other substrate) that is to be processed (e.g., with an etching process, a deposition process, a plasma treatment process, etc.) may be provided in each of the chambers 120.

In an embodiment, an RF power splitter 110 (which is sometimes simply referred to as a splitter 110) is provided between the RF power supply 105 and the plurality of plasma chambers 120. The splitter 110 may take a single RF power input from the RF power supply 105 (which is delivered along transmission line 106, such as a coaxial cable) and distribute the RF power along a plurality of branches to each of the plasma chambers 120. For example, each branch may comprise a transmission line 111_{A}-111_{D}, such as a coaxial cable. In an embodiment, each of the plasma chambers 120 may be coupled to a corresponding RF impedance match 115_{A}-115_{D} in order to provide impedance matching along the branch in order to minimize reflected power back towards the splitter 110 and the RF power supply 105. As noted above, minimizing the reflected power allows for improved power delivery efficiency as well as minimizing stress within the RF power delivery system. The matches 115 may include variable capacitors in order to adjust the impedance to account for changing loads within the plasma chambers 120.

In order to mitigate the amount of power balancing required, output power variation introduced by the RF power splitter 110 and RF impedance matching uniformity within the RF power delivery system 100 may be minimized through design choices used in the creation of the RF power delivery system. However, even the best designs may not achieve the necessary power delivery uniformity. As such, the RF power splitting scheme may utilize a power balancing control system in order to account for changes in impedance loading conditions at the output of each RF impedance match 115 and/or variability of RF power at the input of each RF impedance match 115.

Accordingly, embodiments disclosed herein may include a distributed RF power delivery system that comprises a centralized controller that samples RF transmission line measurements from a set of RF sensors (e.g., voltage-current (VI) sensors or any other sensor capable of detecting reflected RF power) located along each branch of the distributed RF power delivery system. In an embodiment, data sampled from these sensors is used by the centralized controller to perform one or more impedance tuning operations and/or optimized power balancing to ensure that target setpoint RF power is delivered to each load (i.e., to each plasma chamber).

Whereas traditional power delivery control for distributed RF systems is achieved after the impedance matching networks, embodiments disclosed herein implements the control effort in a consolidated manner to enable greater optimization in the delivery of RF load power to each chamber in the network. This optimization is associated in degree of control and the minimization of RF stress across the RF power system. That is, reflected power back through the system is mitigated in order to protect the RF power source from damage in some embodiments.

In order to implement the power balancing control systems described in greater detail herein, an RF power delivery system 100 with an additional controller and sensors is provided. An example of such an RF power delivery system 100 is shown in FIG. 1B. As shown, a plurality of sensors 135 are provided along each branch of the RF power delivery system 100. That is, sensors 135 are provided along transmission lines 111 between the splitter 110 and each of the impedance matches 115. The sensors 135 may be VI sensors in some embodiments. In an embodiment, each of the sensors 135 may be communicatively coupled to a controller 130 by communication paths 136.

The controller 130 may consolidate data from the plurality of sensors 135 in order to implement a power balancing optimization process, such as any of those described in greater detail herein. Generally, the power balancing process may result in the canceling (or minimization) of reflected power along each branch of the RF power delivery system 100. The canceling of reflected power may be the result of a specified “detuning” of one or more of the impedance matches 115. Stated differently, for a given impedance match, the impedance match may be set to a condition where the characteristic impedance is different than the termination impedance. In contrast, the characteristic impedance of a “tuned” impedance match may be substantially equal to the termination impedance.

In an embodiment, the controller 130 may be communicatively coupled to the plurality of impedance matches 115 by communication paths 137. A control effort from the controller 130 may be applied to one or more of the plurality of impedance matches 115 in order to detune the one or more of the plurality of impedance matches by changing a variable capacitance of one or more of the capacitors within the impedance match. In some embodiments, the controller 130 may also be communicatively coupled to the RF power supply 105 by communication path 138 in order to provide control efforts to the RF power supply 105.

As will be described in greater detail herein, the power balancing operations may occur under several different conditions. In a first condition, there is no need for adjusting any of the impedance matches when the load power setpoint is less than or equal to a control threshold. In a second condition, the number of impedance matches to be modified is an even number. In such a condition, antipolar reflection coefficient vectors are generated in order to provide optimal cancelation of reflected power. In a third condition, the number of impedance matches to be modified is an odd number. In such a condition, the maximum detuning to achieve the load power setpoint is used for an even subset of the impedance matches to generate antipolar reflection coefficients, and the remaining impedance match is detuned for the desired load power setpoint. Though, in the third condition a minimal amount of reflected power may be propagated back towards the RF power supply.

More particularly, in the case of a distributed RF power delivery system that comprises four branches (i.e., four plasma chambers coupled to a single RF power source) so that a set of N=4 RF impedance matches is provided at the output of the power splitter, there are five possible conditions that may be investigated for power balancing. These conditions are described in terms of load power at the input of the j^{th} RF impedance matching network that exceeds a load power setpoint P_{LT} that is greater than a control threshold ζ. The set of J matches may be generally classified into the category of

$${P}_{LT}^{j} > {ζ}_{j} , ∀ j or {P}_{LT}^{k} \leq {ζ}_{k} , ∀ k \neq j .$$

Analytically, the five conditions are as follows:

$${P}_{LT}^{k} \leq {ζ}_{k} , ∀ k , J = 0 ; \qquad ( 1 )$$

$${P}_{LT}^{j} > {ζ}_{j} \qquad ( 2 )$$

for the j^{th} RF impedance matching network and

$${P}_{LT}^{k} \leq {ζ}_{k} , ∀ k \neq j ;$$

$${P}_{LT}^{j} > {ζ}_{j} , ∀ j < J = 3 and {P}_{LT}^{k} \leq {ζ}_{k} , ∀ k \neq j ; \qquad ( 3 )$$

$${P}_{LT}^{j} > {ζ}_{j} , ∀ j < J = 4 and {P}_{LT}^{k} \leq {ζ}_{k} , ∀ k \neq j ; and \qquad ( 4 )$$

$${P}_{LT}^{j} > {ζ}_{j} , ∀ j , J = N . \qquad ( 5 )$$

For the five conditions (1)-(5), the first condition (1) requires no power balancing, the second condition (2) requires power balancing for one of the RF impedance matches, the third condition (3) requires power balancing for two of the RF impedance matches, the fourth condition (4) requires power balancing for three of the RF impedance matches, and the fifth condition (5) requires power balancing for all four of the RF impedance matches. While an example where N=4 RF impedance matches is shown as one example, it is to be appreciated that any value of N may be used, and corresponding analytical equations can be constructed in a similar manner to illustrate which of the individual RF impedance matches need to be adjusted to implement the desired power balancing.

In an embodiment, the control objective aims to minimize the reflected power to the RF power supply while adjusting the necessary J RF impedance matches from a total set of J≤N RF impedance matches to meet a load power setpoint of P_{LT}<ζ. This control objective for the J RF impedance matching networks may be achieved with a procedure to obtain reflection coefficients γ ∇j that, when summed, minimize toward zero. This may be generalized in terms of the reflection coefficient γ at the input of the power splitter in accordance with Equation 1.

$$γ = \frac{1}{N} {\sum }_{∀ j}^{J} \vert {γ}_{j} \vert {e}^{j ϕ + j π} \qquad Equation 1$$

With respect to Equation 1, a constellation of cancellation vectors can be generated for an arbitrary ϕ. For the simple case of ϕ:=0, Equation 2 illustrates the calculation for the reflection coefficient γ for the first condition (1) where no power balancing is necessary.

$$γ = \frac{1}{N} {\sum }_{∀ j}^{J} {( - 1 )}^{j} {γ}_{j} \qquad Equation 2$$

For the other conditions where

$${P}_{LT}^{j} = χ , ∀ j , then {\sum }_{∀ j}^{J} {( - 1 )}^{j} {γ}_{j} = 0 .$$

In such conditions, the control objective falls into one of two classes: Class 1 where J is even and the set of γ vectors for each RF impedance match are antipolar for optimal cancellation; or Class 2 where J is odd and the maximum detuning to achieve the corresponding

$${P}_{L T}^{j}$$

are utilized for an even set of antipolar γ vectors, and the remaining RF impedance match is detuned for the desired P_{LT}. However, in Class 2 situations, a portion of reflected power is propagated to the RF power supply. That is, when

$${P}_{LT}^{j} ,$$

∇j is not magnitude parity and even, power from the input of the splitter may be reflected to the RF power supply.

When applying the control objective, such as those described herein, two conditions may apply in order to implement optimal operation of the power balancing scheme. In one condition, the actual load power may exceed the setpoint power, and the power balancing scheme may only decrease the RF power. If a power increase is required, the RF power supply setpoint may need to be adjusted. In another condition, the RF power supply may be set to be in a load leveling mode. If the RF power supply is in a forward power setpoint mode, the power balancing may cause a detuning operation to a set of J RF impedance matches. As such, a portion of the power will be reflected back to the RF power supply. The resulting load power will then be distributed across the splitter outputs.

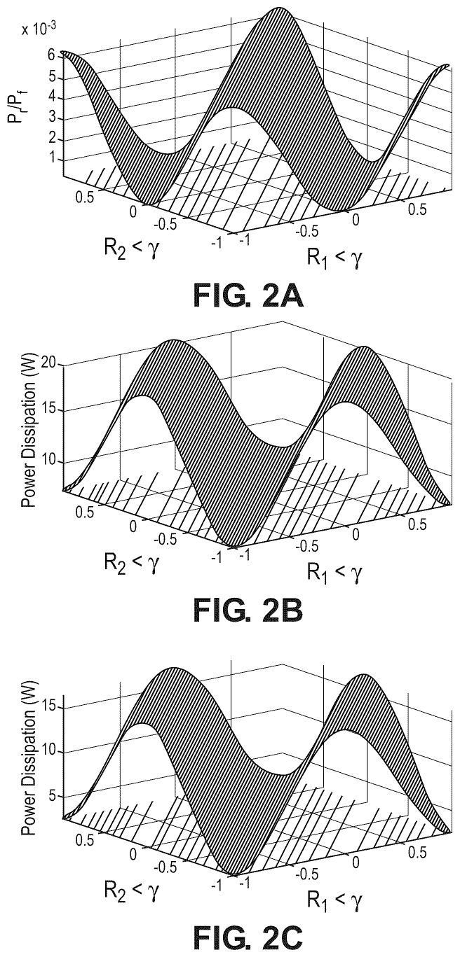

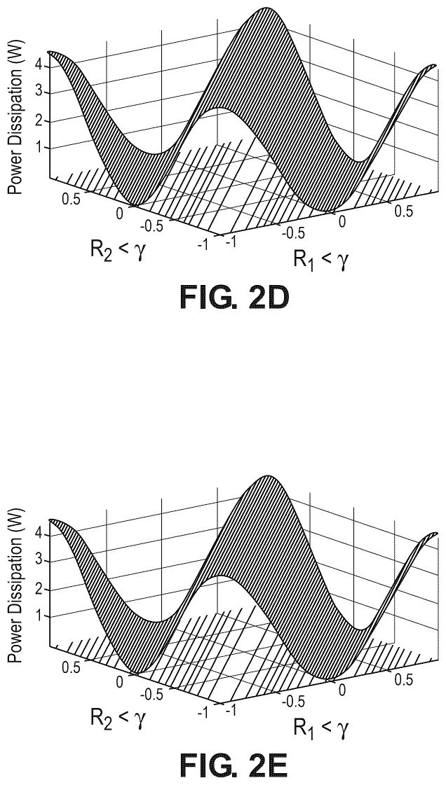

Referring now to FIGS. 2A-2E, a series of plots illustrating simulation results for the power ratio at the splitter input for an even condition is shown, in accordance with an embodiment. Particularly, FIGS. 2A-2E illustrate a system operating under condition 3 described above where two of four RF impedance matches need to be adjusted such that J:=2 of J RF matches qualifies

$${P}_{LT}^{j} > {ζ}_{j} .$$

For example, first and second output ports of the splitter may be power and impedance matched, a third output port may be detuned to a first percentage of power (e.g., 3%), and a fourth output port may be detuned to a second percentage of power (e.g., 2%). Since this is an even number condition, antipolar γ vectors can be generated in order to fully cancel any reflected power.

Referring now to FIG. 2A, a plot of the 3D power ratio (Pᵣ/P_{f}) is shown. For the given condition (i.e., an even condition) the relationship characterized in Equation 1 is clearly demonstrated. For example, when ∠γ₁=∠γ₂±π, two troughs are formed for γ=0. The cancellation created by Σ_{∇jγj} yields no reflected RF power to the RF power supply from the splitter. FIGS. 2B-2E show the power dissipated in a resistor of the splitter for each branch of the system. When γ=0, the power dissipated is at a maximum value for j=1 and j=2. Since detuning is not required for j=3 and j=4, only nominal power is dissipated in the associated resistors.

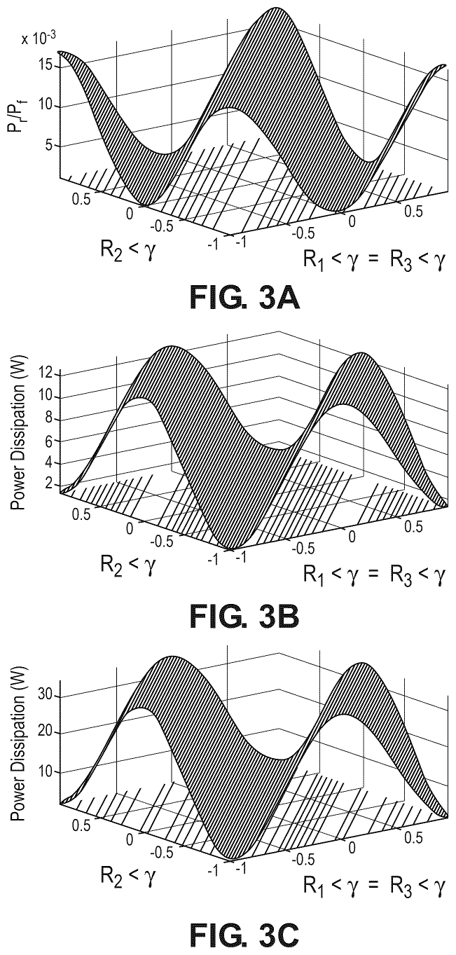

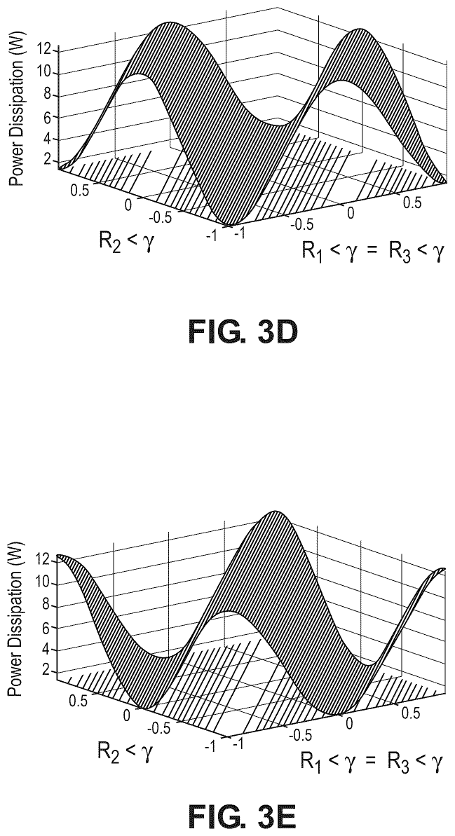

Referring now to FIGS. 3A-3E, a series of plots illustrating simulation results for the power ratio at the splitter input for an odd condition is shown, in accordance with an embodiment. Particularly, FIGS. 3A-3E illustrate a system operating under condition 4 described above where three of four RF impedance matches need to be adjusted such that J:=3 of J RF matches qualifies

$${P}_{LT}^{j} > {ζ}_{j} .$$

For example, a first output port of the splitter may be power and impedance matched, and the second through fourth output ports may be detuned. Since this is an odd number condition, antipolar γ vectors may not be able to be generated in order to fully cancel all reflected power.

Referring now to FIG. 3A, a plot of the 3D power ratio (Pᵣ/P_{f}) is shown. For the given condition (i.e., an odd condition) the relationship characterized in Equation 1 indicates that the set of γⱼ vectors can cancel two elements, but the third element cannot be fully reduced. For example, the resulting

$$γ = \frac{\sum ∀ j γ j}{4}$$

results in RF power being reflected to the RF power supply when ∠γ₁=∠γ₂±π. FIGS. 3B-3E show the power dissipated in a resistor of the splitter for each branch of the system. When γ is at a minimum, the power dissipated is at a maximum value for j=1, j=2, and j=3, while the remaining resistor dissipates nominal power.

In an embodiment, the creation of antipolar vectors y may be implemented with a detuning algorithm that utilizes data obtained from sensors (such as VI sensors 135 described in greater detail above). The detuning algorithm may seek to maximize power transfer, which can be accomplished by minimizing reflected power P_{R} which is defined as

$${P}_{R} = \frac{{\vert {V}_{x , f}^{r} ( f ) \vert}^{2}}{{z}_{0}} ,$$

where Z₀ is the characteristic impedance and V is voltage. In an embodiment, the detuning algorithm may reduce the complex quantities of

$${V}_{x , f}^{i} ( t ) , {V}_{x , f}^{r} ( t ) , {I}_{x , f}^{i} ( t ) , and {I}_{x , f}^{r} ( t )$$

(which may each be a computed variable) in order to achieve a minimization of P_{R}. Tuning control parameters are computed transmission line variables and utilized to determine the optimal impedance match condition for maximum RF power transfer from the input to the output of the RF impedance match circuit. The impedance detuning algorithm formulates a vector u of three elements to control the impedance of variable elements in the RF impedance match circuit. The coordinated trajectory is controlled by adjusting the variable impedance with positioning one or more corresponding actuators to minimize each of the three elements of u. In an embodiment, the three elements of u may comprise:

$${u}_{1} = ( \frac{{V}_{x , f}^{r} {I}_{x , f}^{r}}{{V}_{x , f}^{i} {I}_{x , f}^{i}} ( \frac{{I}_{x , f}^{r}}{{I}_{x , f}^{i}} ) * ) * ; \qquad ( 1 )$$

$${u}_{2} = \frac{{V}_{x , f}^{r}}{{V}_{x , f}^{i}} ; and \qquad ( 2 )$$

$${u}_{3} = \frac{{I}_{x , f}^{r}}{{I}_{x , f}^{i}} . \qquad ( 3 )$$

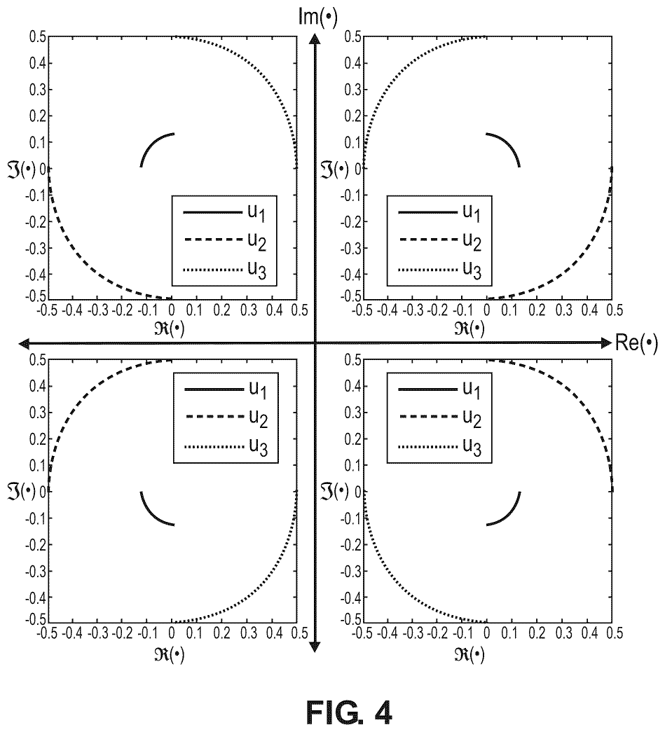

In an embodiment, the elements of u produce a vector that yields an orientation within the impedance tune space to match the output load conditions. The u element orientation is shown in FIG. 4. As illustrated, the plot is divided into four quadrants. In each quadrant there is a unique plot that indicates the position of the u vector elements. For example, the plot in quadrant 1 (i.e., positive real and positive imaginary) has the u₁ element is positioned in sub-quadrant 1 (of quadrant 1), while the u₂ element is in sub-quadrant 4 (of quadrant 1), and the u₃ element is positioned in sub-quadrant 3 (of quadrant 1). As a result, each element of u is positioned in a different sub-quadrant and an element of u never overlaps a sub-quadrant of a different element of u. Accordingly, an analytical orientation of the present u vector mapping towards an optimal impedance tune for power transfer is provided. The plots in the other quadrants of FIG. 4 illustrate the orientation of the u vector such that no quadrant shares multiple elements of the u vector. For each plot in FIG. 4, the relationship of |u₁|=|u₂|³=−|u₃|³.

In an embodiment, a second vector dx is introduced to provide a linear combination of a dot product with the u vector. The i^{th} update to the first capacitor (C₁) position may be controlled by Equation 3. Similarly, the i^{th} update to the second capacitor (C₂) position may be controlled by Equation 4. In Equation 3 and Equation 4, d₁ and d₂ are vectors related to the first capacitor C₁ and the second capacitor C₂, respectively.

$${C}_{1 , i} = {C}_{1 , i - 1} + ℜ ( {d}_{1} \cdot u ) \qquad Equation 3$$

$${C}_{2 , i} = {C}_{2 , i - 1} + 𝔍 ( {d}_{2} \cdot u ) \qquad Equation 4$$

In an embodiment, detuning the RF impedance matching network may include a reconstruction of the u vector. For detuning to achieve a power balancing objective, the adjustment to the variable elements C₁ and C₂ of the j^{th} RF impedance matching network are adjusted from a reflection coefficient of zero to γⱼ. This may be done by the formulation of the j^{th} u vector to Equations 3 and 4 with the elements: (1) u_{1,j}=u₁−γⱼ³; (2) u_{2,j}=u₂−γⱼ; and (3) u_{3,j}=u₃+γⱼ. In an embodiment, γⱼ is a non-zero value and/or a complex quantity.

It is to be appreciated that the direct outputs from the VI sensors in the distributed RF power delivery system may not directly correspond to the true transmission line values. Accordingly, transmission line theory may be used as a basis for generating a framework of models. In an embodiment, a first model is developed to convey the parameters attributing to the load voltages and currents. A second model may be used to describe the propagating waveforms on the transmission line. The use of one or both of the models can be used to simplify the impedance tuning algorithm.

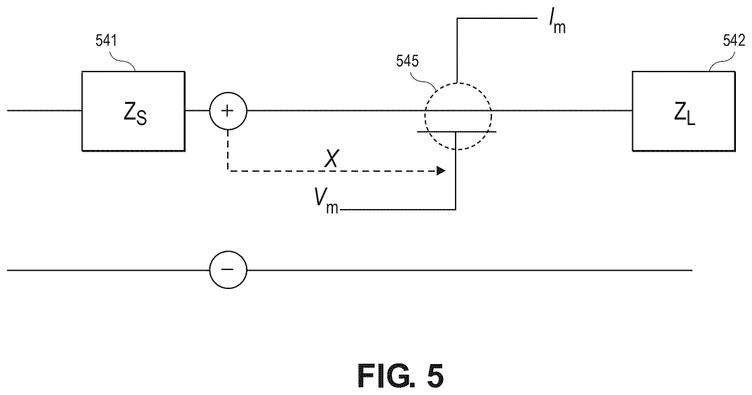

Referring now to FIG. 5, a schematic of a transmission line with a VI sensor 545 installed at a position x along a transmission line is shown, in accordance with an embodiment. The VI sensor 545 may output a current reading Iₘ and a voltage reading Vₘ. The transmission line may have a source impedance Zₛ 541 and a load impedance Z_{L} 542. For the expression

$${V}_{x , f} ( t ) = {V}_{x , f}^{i} ( t ) + {V}_{x , f}^{r} ( t )$$

where the incident voltage wave-form at position x and frequency f is described by

$${V}_{x , f}^{r} ( t ) = {V}_{0}^{-} {e}^{γ x} ,$$

and the reflection voltage is described by

$${V}_{x , f}^{i} ( t ) = {V}_{0}^{+} {e}^{- γ x}$$

where γ represents the complex propagation constant with a real term a for the transmission line loss and the imaginary component β for the velocity propagation. Transmission line theory describes the relationship and reflected wave forms as the complex quantity

$$Γ = \frac{{V}_{0}^{-}}{{V}_{0}^{+}}$$

for the transmission line defined with the characteristic impedance

$${Z}_{0} = \frac{γ}{R + j 2 π fL} ,$$

where R and L are the series components of the transmission line from the position x of the load.

$${I}_{x , f} ( t ) = {I}_{x , f}^{i} ( t ) + {I}_{x , f}^{r} ( t )$$

represents the current flow at the position x at frequency f with

$${I}_{x , f}^{r} ( t ) = \frac{1}{{z}_{0}} {V}_{0}^{+} {e}^{- γ x} .$$

Finally, Equation 5 and Equation 6 describe the time-varying voltage and current, where ϕ^{±} indicates the phasor of the incident and reflected voltages.

$${V}_{x , f} ( t ) = \vert {V}_{0}^{+} \vert cos ( 2 π ft - β x + {ϕ}^{+} ) {e}^{- α x} + \vert {V}_{0}^{-} \vert cos ( 2 π ft + β x + {ϕ}^{-} ) {e}^{α x} \qquad Equation 5$$

$${I}_{x , f} ( t ) = \frac{\vert {V}_{0}^{+} \vert}{{Z}_{0}} cos ( 2 π ft - β x + {ϕ}^{+} ) {e}^{- α x} - \frac{\vert {V}_{0}^{-} \vert}{{Z}_{0}} cos ( 2 π ft + β x + {ϕ}^{-} ) {e}^{α x} \qquad Equation 6$$

This first model effectively creates a frequency dependent transfer function that describes the input relationship of the transmission line parameters with the voltage and current sensor outputs.

In an embodiment, the second model development starts off with the general expression for the incident and reflected voltage initially formulated earlier in the transmission line model. The voltage expressions for the incident and reflected waves at position x are defined by Equation 7, where v(x,f) and i(x,f) are complex quantities as defined as v(x,f)=|V|e^{-j(ωt+ϕ}^{ᵥ}⁾ and i(x,f)=|I|e^{-(ωt+ϕ}^{ᵢ}⁾.

$$[ \begin{matrix}{V}_{x , f}^{i} ( t ) \\ {V}_{x , f}^{t} ( t )\end{matrix} ] = \frac{1}{2} [ \begin{matrix}1 & {Z}_{0} \\ 1 & - {Z}_{0}\end{matrix} ] \times [ \begin{matrix}v ( x , f ) \\ i ( x , f )\end{matrix} ] \qquad Equation 7$$

In an embodiment, a ratio of the time varying complex quantities yields

$$z = \frac{\vert V \vert}{\vert I \vert} {e}^{- j {θ}_{v i}} ,$$

where θᵥᵢ=ϕᵥ−ϕᵢ. The power of the incident voltage is

$${P}_{F} = \frac{{\vert {V}_{x , f}^{i} ( t ) \vert}^{2}}{{Z}_{0}}$$

and the power of the reflected wave is

$${P}_{R} = \frac{{\vert {V}_{x , f}^{r} ( t ) \vert}^{2}}{{Z}_{0}} .$$

With the load power defined as P_{L}=P_{F}−P_{R}, the incident and reflected voltages are incorporated so that

$${P}_{L} = \frac{1}{{Z}_{0}} \{ {\vert {V}_{x , f}^{i} ( t ) \vert}^{2} - {\vert {V}_{x , f}^{r} ( t ) \vert}^{2} \} .$$

Accordingly, the current expressions for the incident and reflected waves at position x are defined in Equation 8, where v(x,f) and i(x,f) are complex quantities as defined as v(x,f)=|V|e^{-j(ωt+ϕ}^{ᵥ}⁾ and i(x,f)=|I|e^{-(ωt+ϕ}^{ᵢ}⁾.

$$[ \begin{matrix}{I}_{x , f}^{i} ( t ) \\ {I}_{x , f}^{r} ( t )\end{matrix} ] = \frac{1}{2} [ \begin{matrix}\frac{1}{{Z}_{0}} & 1 \\ \frac{- 1}{{Z}_{0}} & 1\end{matrix} ] \times [ \begin{matrix}V ( x , f ) \\ {I}_{m} ( x , f )\end{matrix} ] \qquad Equation 8$$

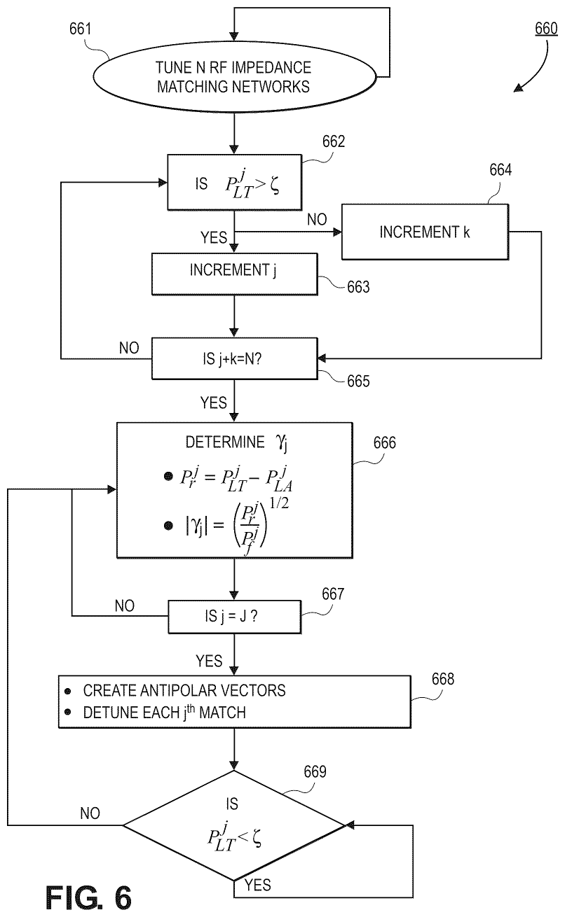

Referring now to FIG. 6, a process flow diagram for describing a process 660 for power balancing a distributed RF power delivery system is shown, in accordance with an embodiment. In an embodiment, the process 660 may begin with operation 661, which comprises tuning N RF impedance matching networks. In an embodiment, the tuning process may be used to reduce reflected power so that the load power setpoint is below a control threshold for each of the branches in the distributed RF power delivery system. In an embodiment, the N number of RF impedance matching networks may include two or more RF impedance matching networks. In a particular embodiment, N is equal to four.

In an embodiment, the process 660 may continue with operation 662 where it is determined if the load power setpoint is greater than the control threshold (i.e., whether

$${P}_{LT}^{j} > ζ ) .$$

If the condition is satisfied, the j value is incremented at operation 663, where j represents the number of RF impedance matching networks that need to be adjusted. If the condition is not satisfied, the k value is incremented at operation 664, where k represents the number of RF impedance matching networks that do not need to be adjusted. After incrementing j and/or k values, the process 660 may continue to operation 665, where it is determined if j+k=N. Once j+k=N, all RF impedance matching networks have been accounted for and the process 660 may continue.

In an embodiment, the process 660 may continue with operation 666, which comprises determining the reflection coefficient γⱼ so that

$${P}_{r}^{j} = {P}_{LT}^{j} - {P}_{LA}^{j} and \vert {γ}_{j} \vert = {( \frac{{P}_{r}^{j}}{{P}_{f}^{j}} )}^{1 / 2} .$$

The reflection coefficient γⱼ may be optimized so that a set of J impedance matching networks are assigned the corresponding γ₁ that is subsequently applied to the impedance tuning operation to provide a detuned result for the j^{th} impedance matching network so that

$${P}_{LT}^{j} = {P}_{F}^{j} - {P}_{R}^{j}$$

is satisfied. The operation of detuning may create a non-zero

$${P}_{R}^{j} ,$$

which creates a quantity of RF power to be reflected to the j^{th} output of the power splitter. Equation 1 above provides the general equation to satisfy the phase relation among the set of γⱼ to minimize γ. An optimization procedure to assign the orientation of γⱼ∇J within the complex plane to minimize γ is provided herein.

In an embodiment, the optimization procedure may begin when |γⱼ| is equal ∇J=N, the optimization to orient |γⱼ| is achieved with Equation 2 for the case

$${P}_{LT}^{j} > {ζ}_{j} , ∀ j ,$$

J=N. The optimization procedure treats the set of γⱼ as a bounded random variable between 0 and γₘₐₓ, and has a low probability that |γⱼ| is parity ∇J=N. For this reason, a procedure to orient the set of γⱼ to minimize γ is needed to complement the phase relationship γⱼ∇J=N described in Equation 1. For example, if |yⱼ₌₁| is three times the

$${\sum }_{∀ j \neq 1}^{J} \vert {γ}_{j} \vert ,$$

Equation 2 is further optimized by vector orientation for magnitude with the preferential assignment of the following ϕ:=0 phase relationship to provide Equation 9.

$$γ = \frac{- {γ}_{1} + {γ}_{2} + {γ}_{3} + {γ}_{4}}{N} \qquad Equation 9$$

The optimization by magnitude utilizes the phase optimization of 0 in Equation 1 so that

$${\sum }_{∀ j \neq 1}^{J} \vert {γ}_{j} \vert = \vert {γ}_{j = 1} \vert .$$

In an embodiment, an analytical sorting method to determine the optimal phase and magnitude of γⱼ∇J to achieve a |γ| minimum with the linear combination of y=Ax where x=[γ₁ γ₂ γ₃ γ₄]^{T} and

$$A = [ \begin{matrix}1 & 1 & 1 & 1 \\ 1 & 1 & 1 & - 1 \\ 1 & 1 & - 1 & 1 \\ 1 & 1 & - 1 & - 1 \\ 1 & - 1 & 1 & 1 \\ 1 & - 1 & 1 & - 1 \\ 1 & - 1 & - 1 & 1 \\ 1 & - 1 & - 1 & - 1 \\ - 1 & 1 & 1 & 1 \\ - 1 & 1 & 1 & - 1 \\ - 1 & 1 & - 1 & 1 \\ - 1 & 1 & - 1 & - 1 \\ - 1 & - 1 & 1 & 1 \\ - 1 & - 1 & 1 & - 1 \\ - 1 & - 1 & - 1 & 1 \\ - 1 & - 1 & - 1 & - 1\end{matrix} ]$$

In an embodiment, the optimal linear combination of y=Ax to minimize |γ| is min(y). In some embodiments, the construction of A may be enhanced to yield the same objective of minimizing |γ| by deprecating some of the row entries (e.g., the first and last rows may be eliminated for computational efficiency. Additionally, pairs of ±1 elements within a row entry of A may be replaced with a pair of conjugate values so that the linear combination of a conjugate pair sums to e^{jϕ+π}.

In an embodiment, the process may continue with operation 667, where it is determined if j=J. If this condition is not satisfied, then the process 660 may continue back to operation 666. If the condition is satisfied, then the process 660 may continue to operation 668, wherein antipolar vectors are generated to cancel reflected power in an even set of RF impedance matches, and any remaining impedance matches are detuned to minimize reflected power back to the RF power source.

In an embodiment, the process may continue with operation 669, where it is determined if

$${P}_{LT}^{j} < ζ .$$

If the condition is met, the power balancing is completed, and if the condition is not met, then the process 660 loops back to operation 666 for further optimization.

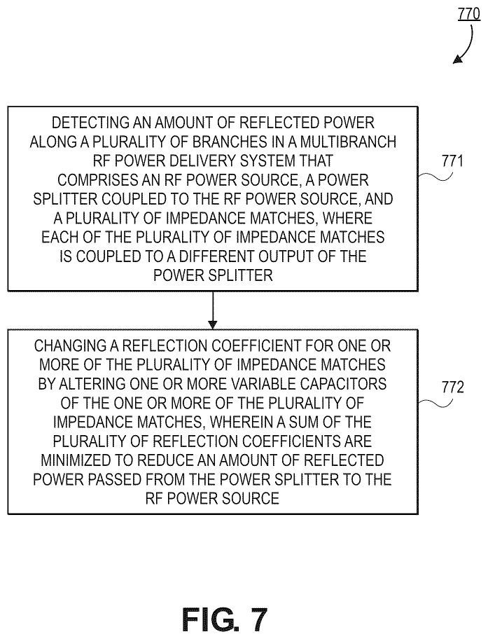

Referring now to FIG. 7, a process flow diagram of a process 770 for power balancing a multi-branch RF power delivery system is shown, in accordance with an embodiment. In an embodiment, the multi-branch RF power delivery system may comprise an RF power source and a power splitter coupled to the RF power source. In an embodiment, a plurality of RF impedance matches are each coupled to a different output of the power splitter. In an embodiment, the process 770 may start with operation 771, which comprises detecting the reflected power between the plurality of impedance matches and the power splitter with a plurality of sensors, such as VI sensors. In an embodiment, a different sensor is provided along the transmission lines between each RF impedance match and the power splitter.

In an embodiment, the process 770 may continue with operation 772, which comprises changing a reflection coefficient for one or more of the plurality of impedance matches by altering one or more variable capacitors of the one or more of the plurality of impedance matches. In an embodiment, a sum of the plurality of reflection coefficients are minimized to reduce an amount of reflected power passed from the power splitter to the RF power source.

In an embodiment, the one or more of the plurality of impedance matches is an even number of impedance matches. In such an embodiment, the reflection coefficients of the even number of impedance matches are antipolar and fully cancel. In other embodiments, the one or more of the plurality of impedance matches is an odd number of impedance matches. In such an embodiment, a first subset of the odd number of impedance matches comprises an even number of impedance matches with antipolar reflection coefficients, and a second subset of the odd number of impedance matches comprises a single impedance match.

In an embodiment, a sum of the plurality of reflection coefficients is zero to provide no reflected power to the RF power source. Additionally, in an embodiment changing the reflection coefficient for one or more of the plurality of impedance matches may result in detuning the one or more of the plurality of impedance matches so that a characteristic impedance is different than a termination impedance.

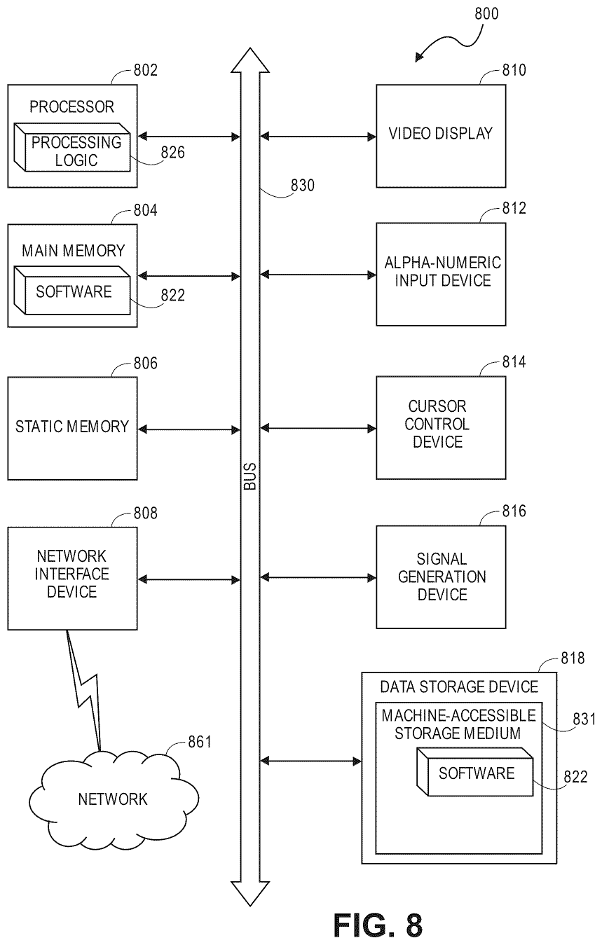

Referring now to FIG. 8, a block diagram of an exemplary computer system 800 of a processing tool is illustrated in accordance with an embodiment. In an embodiment, computer system 800 is coupled to and controls a distributed RF power distribution system and power balancing optimization processes for improved RF power delivery.

Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using microwave coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include systems that include a distributed RF power distribution system and power balancing optimization processes for improved RF power delivery.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a radio frequency (RF) power supply;
an RF power splitter electrically coupled to the RF power supply, wherein the RF power splitter comprises a plurality of outputs;
a plurality of RF impedance matches, wherein each of the plurality of RF impedance matches is electrically coupled to a different one of the plurality of outputs of the RF power splitter;
a plurality RF sensors, wherein each of the plurality of RF sensors is configured to measure a voltage and/or a current along a different one of a plurality of transmission lines that couple each of the plurality of outputs of the RF power splitter to a different one of the plurality of RF impedance matches; and
a controller communicatively coupled to the plurality of RF sensors and the plurality of RF impedance matches, wherein the controller is configured to balance power that passes through the plurality of RF impedance matches with a detuning operation.

2. The apparatus of claim 1, further comprising:
a plurality of plasma chambers, wherein each of the plurality of RF impedance matches is electrically coupled to a different one of the plurality of plasma chambers.

3. The apparatus of claim 1, wherein the detuning operation comprises detuning one or more of the plurality of the RF impedance matches so that, for each of the plurality of RF impedance matches, a forward power through the RF impedance match minus a reflected power from the RF impedance match is equal to a load power setpoint for the RF impedance match.

4. The apparatus of claim 3, wherein the reflected power from the RF impedance match is non-zero.

5. The apparatus of claim 3, wherein the detuning operation further comprises applying a different reflection coefficient to each of the plurality of RF impedance matches to minimize the reflected power while still keeping the load power setpoint being equal to the forward power minus the reflected power.

6. The apparatus of claim 1, wherein the detuning operation results in a characteristic impedance of one of the plurality of transmission lines being different than a termination impedance of one of the RF impedance matches that is coupled to the one of the plurality of transmission lines.

7. The apparatus of claim 1, wherein the plurality of RF impedance matches comprises four or more RF impedance matches.

8. The apparatus of claim 1, wherein the detuning operation comprises detuning an odd number of the plurality of RF impedance matches.

9. The apparatus of claim 1, wherein the detuning operation comprises detuning an even number of the plurality of RF impedance matches.

10. The apparatus of claim 1, wherein the detuning operation comprises detuning all of the plurality of RF impedance matches.

11. A method, comprising:
detecting an amount of reflected power along a plurality of branches in a multi-branch RF power delivery system that comprises:
a radio frequency (RF) power source;
a power splitter coupled to the RF power source; and
a plurality of impedance matches, wherein each of the plurality of impedance matches is coupled to a different output of the power splitter, and wherein the reflected power is detected between the plurality of impedance matches and the power splitter; and
changing a reflection coefficient for one or more of the plurality of impedance matches by altering one or more variable capacitors of the one or more of the plurality of impedance matches, wherein a sum of the plurality of reflection coefficients are minimized to reduce an amount of reflected power passed from the power splitter to the RF power source.

12. The method of claim 11, wherein the one or more of the plurality of impedance matches is an even number of impedance matches, and wherein the reflection coefficients of the even number of impedance matches are antipolar.

13. The method of claim 11, wherein the one or more of the plurality of impedance matches is an odd number of impedance matches, and wherein a first subset of the odd number of impedance matches comprises an even number of impedance matches with antipolar reflection coefficients, and wherein a second subset of the odd number of impedance matches comprises a single impedance match.

14. The method of claim 11, wherein the sum of the plurality of reflection coefficients is zero.

15. The method of claim 11, wherein the reflected power is sensed with a plurality of RF sensors between the power splitter and the plurality of impedance matches.

16. The method of claim 11, wherein changing a reflection coefficient for one or more of the plurality of impedance matches results in detuning the one or more of the plurality of impedance matches so that a characteristic impedance is different than a termination impedance.

17. A method, comprising:
tuning a plurality of impedance matches in a radio frequency (RF) power distribution network;
determining if a load power setpoint is greater than a control threshold for each of the plurality of impedance matches; and
generating antipolar vectors for reflection coefficients for a first subset of the plurality of impedance matches where the load power setpoint is greater than the control threshold, and wherein the first subset comprises an even number of impedance matches.

18. The method of claim 17, further comprising:
detuning a second subset of the plurality of impedance matches where the load power setpoint is greater than the control threshold, and wherein the second subset comprises a single impedance match.

19. The method of claim 17, wherein the load power setpoint is equal to a forward power minus a reflected power, and wherein the reflected power is non-zero.

20. The method of claim 17, wherein the RF power distribution network is used to provide RF power to a plurality of plasma chambers.
